(19) United States
(12) Patent Application Publication
(10) Pub. No.: US 2017/0003347 A1
(43) Pub. Date: Jan. 5, 2017

(54) ENCODING OF FAULT SCENARIOS OF A MANYCORE PROCESSOR

(71) Applicant: COMMISSARIAT A L'ENERGIE ATOMIQUE ET AUX ENERGIES ALTERNATIVES, Paris (FR)

(72) Inventor: Mohamed BENAZOUZ, MONTREUIL (FR)

(21) Appl. No.: 15/113,020

(22) PCT Filed: Jan. 28, 2015
(86) PCT No.: PCT/EP2015/051714

§ 371 Date: Jul. 20, 2016

(30) Foreign Application Priority Data
Feb. 11, 2014 (FR) 1451042

(51) Int. Cl. G01R 31/317; G01R 31/3177

(52) U.S. Cl. CPC G01R 31/31718; G01R 31/31703; G01R 31/31704; G01R 31/3177

(57) ABSTRACT

A method implemented by computer for compressing and decompressing all the fault scenarios of a processor comprising computation units interconnected by a communication network having topology symmetries, each fault scenario corresponding to the number and the location of one or more failing computation units and the method comprises the steps of reception or determination of one or more topology symmetries; determination of the equivalent scenarios by means of said topology symmetries; each of the fault equivalence classes being associated with a resource allocation solution in terms of mapping and routing. Different developments include the determination or the application of an inference engine, of identifiers associated with the fault scenarios, of combinatorial exploration techniques, of compression rates, of reconfiguration of the processor and of classification of the processor in a range. A program product and associated systems are also described.

### FIELD OF THE INVENTION

The invention relates to the field of parallel computation and in particular that of the allocation of computation and communication resources, that is to say the mapping and the routing of the software applications on single-processor or multi-processor computation platforms.

### STATE OF THE ART

A “multicore” microprocessor is a processor that has several physical cores which work in parallel. These days, the so-called “manycore” systems describe systems comprising tens or even hundreds of cores. These computation units, which can be clustered or not, are interconnected, for example by a communication network (network on chip, or NoC).

When fabricating these processors or manycore “chips”, errors can occur. The result is processors that have degraded in a number of places (location of the failures) and at different levels (number of failures), the parts concerned being deactivated.

It is desirable to be able to market such degraded processors. More generally, there is a need for methods and associated systems that make it possible to improve the yield of manycore processors (Yield Enhancement) on leaving the factory, i.e. by making it possible to exploit (and therefore market) processors which do not entirely correspond to the architecture initially requested.

Most of the current multi-manycore processors use shared buses. These circuits tend to eliminate the problem of reconfiguration by eliminating the combinatorial explosion of possible failure scenarios. In fact, the patent literature does not as yet even mention this technical problem (and, a fortiori, does not propose any technical solution). However, these circuits with shared buses are not scalable, and the next generations of manycore processors will probably have to dispense with this type of circuit to adopt communication networks for which this technical problem will become more acute.

Zhang et al. [Lei Zhang et al. “On Topology Reconfiguration for Defect-Tolerant NoC-Based Homogeneous Manycore Systems” in IEEE Transactions On Very Large Scale Integration (VLSI) Systems, Vol. 17, No. 9, September 2009] discloses a technique based on virtualization to resolve the problem of deployment of an application on different irregular architectures which result in failures in fabrication of one and the same initial architecture. The virtualization proposes unifying all these degraded physical architectures under a single reference virtual topology.

In order to have the spare resources necessary for the reconfiguration, this approach offers only a part of the total power actually present on the chip, whether degraded or not (so-called AMAD, As Many As Demand, logic). Thus, only a single and unique power range can be defined. The degraded processors which do not offer enough resources for reconfiguration will be rejected. Such an approach is efficient only if it is applied to non-clustered manycore architectures (in other words, when the redundancy is at the computation core level, the cost associated with the spare cores being minimized). For clustered manycore architectures (corresponding to the most common case), the redundancy at cluster level would be too costly and difficult to make cost effective. Furthermore, the abstraction of the physical NoC as produced greatly reduces the routing possibilities actually offered and risks even reducing the realizability space. Furthermore, for the adopted reconfiguration algorithm, no guarantee concerning the possibility of reconfiguration regardless of the degraded chip is presented. Ultimately, the approach proposed by Zhang has limitations.

The only known approach does not therefore constitute an adequate solution. The different solutions proposed herein remedy the known drawbacks, at least partly.

### SUMMARY OF THE INVENTION

A method and a device for the compact encoding of fault (or failure) scenarios of a processor (or “chip”) exploiting the symmetries of interconnection of an architecture are disclosed.

According to one aspect of the invention, a method for mapping and/or routing of applications on degraded manycore processors is disclosed. The processors are classified in ranges. Each range groups together processors with the same computation capacity, fixed and known in advance, but for which the locations of the faults are known only when the processor is switched on (i.e. “online”). The mapping/routing phases are, for their part, usually performed “offline” (for example during the compilation phase) because they are highly time consuming and computation power intensive. This incomplete knowledge of the architecture at the compilation phase means reiterating the mapping/routing for all the possible fault scenarios and saving the solutions in a single binary in order to cope with all the situations in the deployment of the application on a given range. However, the number of possible scenarios per range is very great.

In order to reduce the number of scenarios to be processed, it is advantageous to exploit the symmetry of the interconnects. This amounts to compressing the space of the scenarios at the same time making it possible to compress the binary and the solving time. In one embodiment, there is disclosed a technique for compressing (e.g. reducing) the space of the fault scenarios by exploiting one or more symmetries. This compression makes it possible to reiterate the mapping/routing algorithms on a comparatively small number of fault scenarios and thus make it possible to use various, more or less optimized, exploration techniques.

The mapping/routing solutions for the scenarios not included in this reduced set will subsequently be able to be obtained by decompression, said decompression being able to be executed at the chip level. A decompression has a duty to be rapid and to consume little in terms of computation power and memory given the embedded context.

Advantageously, no limit is imposed as to the maximum number of faults. All the processors can be exploited, classified in a range and marketed. Compared to the approaches of AMAD type, like Zhang, the rejection rate on leaving the factory will therefore be lower according to the invention (so-called AMAA, As Many As Available, logic). In other words, computation resources present on a chip will be able to be fully utilized, by classifying the degraded processors in a number of marketed ranges, for example according to the level or number of failures. For example, if an application does not need all the power offered by a range, it will be able to be deployed on a lower range which will necessarily be less expensive and will deliver sufficient performance. For example, if an application needs 9 computation clusters, the range with 9 functional clusters will be used. There will be no need to use a higher range with 10, 11 or 12 clusters (unlike the virtualization technique which will need more clusters to reconstruct its virtual architecture with 9 clusters).

Advantageously, the symmetry inherent to the architectures (through the interconnects between the computation units) is exploited.

The symmetry makes it possible to identify equivalent fault cases, to within a few operations of symmetry. According to these operations, the space of the architectures derived from a same range can be compressed. In one step, the equivalent cases are detected and grouped together in so-called equivalence classes. In another step, the mapping/routing solutions are computed (one solution per class). Generally, after the start up of the processor and/or the identification of the fault case and its class, the mapping/routing solution for this class can be decoded/decompressed in order to reconfigure it.

Advantageously, the overall symmetry offered by all the interconnection elements is exploited, and generically. This implementation is particularly tricky and technically difficult. The existing techniques for exploiting symmetry in distant technical domains can make use of that of the “inference engines” to detect the equivalent cases. These engines are generally of exponential complexity and the optimizations that are generally made to them degrade their generic nature. Furthermore, the convergence of the inference engines is not guaranteed in the general case (i.e. computation time not guaranteed), any more than the accuracy thereof (i.e. equivalent cases may be itemized a number of times because they have not been detected as such by the inference engine).

Advantageously, the exploitation of the symmetry which is proposed is characterized by its optimality (e.g. two equivalent cases are itemized only once), its speed (e.g. associated with a very low algorithmic complexity) and its genericity (e.g. it can easily be adapted to the different architectures).

Advantageously, a new inter-processor (or inter-cluster) distance or distance normal is proposed which takes account of the symmetry.

Advantageously, a way of using this distance to detect and identify the equivalent scenarios is proposed.

The next generations of manycore processors could indeed adopt NoCs of “2D Torus”, “3D Torus” or other types that are very rich in symmetries. The embodiments described herein would comparatively advantageously take advantage of these architectures.

Experimental results have been obtained. The approach disclosed was tested for a manycore provided with a 2D Torus NoC with 4×4 clusters. The results indicate a reduction of the scenario space of the order of 98% to 99%. For example, for the case of 8 faults, with no compression tool, 12870 different scenarios have to be processed and their mapping/routing solutions saved. By applying the technique presented, only 153 scenarios have to be saved, the solutions for the other cases being obtained by the operations of symmetry described. These results represent just as much a storage saving as a processing time saving. In effect, by assuming for example that the processing (mapping/routing) requires a time of the order of 10 seconds per fault scenario, then the processing without compression technique of all the range of 8 faults takes more than 35 hours, against less than 21 minutes by using the method described herein. Furthermore, by following an iterative approach, with the slightest modification, the entire process has to be redone. The time saving can therefore be extremely substantial.

Advantageously, the invention will be applicable for the embedded solutions (that have limited computation and memory resources).

Advantageously, the symmetry can be used to reduce the number of architectures to be processed in order to guarantee the deployment of an application over a range of processors which offer the same computation capacity but that have different architectures.

Advantageously, the invention can also be used for “online” reconfiguration when a fault occurs during execution and there is a need for a new mapping/routing solution in order to reconfigure the chip and continue to execute the application.

Advantageously, the invention can be used for “online” reconfiguration preventively, for example in order to preserve the life span of a chip. Thus, when the temperature of a zone of the chip reaches a certain threshold, certain computation resources may be deactivated in that zone and are replaced by other resources obtained from another zone where the temperature is less which may dictate or trigger a reconfiguration (Dynamic Thermal Management).

Advantageously, the method can be used to assess the resistance to faults of certain NoC structures. In particular, in the context of development of new manycore architectures, processors will be able to be selected that have an architecture that allows a high compression rate for the fault scenarios spaces.

Advantageously, the methods disclosed will be able to be applied to the mapping of the ports (LUT) and the routing of communications in the Field-Programmable Gate Array FPGA solutions, whether for the purposes of simulation or of implementation. By using the symmetry or symmetries which characterize FPGAs, mapping/routing techniques (based on graphs) can be accelerated by detecting the equivalent solutions, thus reducing the search space (Symmetry Breaking).

Advantageously, it will be possible to proceed with a uniform partitioning of the hardware, in order to create hierarchical levels. The use of symmetry makes it possible to identify equivalent blocks which then join a hierarchical level. A number of levels, nested or not, can be constructed and can subsequently be used to develop and optimize hierarchical (by “floor”) partition or mapping or routing tools.

A method is disclosed that is implemented by computer for compressing all the fault scenarios of a processor comprising computation units interconnected by a communication network exhibiting topology symmetries, each fault scenario corresponding to the number and the location of one or more failing computation units and the method comprising the steps of reception or determination of one or more topology symmetries; of determination of the equivalent scenarios by means of said topology symmetries; each of the fault equivalence classes being associated with a resource allocation solution determining a specific mapping of the tasks of the applications on the computation units and a specific routing of the data exchanges over the communication network.

The invention manipulates one or more “topology symmetries”. A “topology symmetry” can also be called “topological symmetry” (“symmetry in topology” or “symmetry of the topology”). The concept of topology can, for example and in certain cases, refer to the graph of the topology. The expression “topology symmetry” or “topological symmetries” must be taken in its broadest sense. In particular, a topological symmetry cannot be reduced to just symmetries of geometry. A topological symmetry can be logical and/or physical; i.e. “logical” or “physical” or “logical and physical”. The physical arrangement, that is to say the spatial configuration of the network is called physical topology. The logical topology represents the manner in which the data travel in the communication lines. The symmetries according to the invention can correspond to “logical” or “functional” or “architectural” geometries, that is to say operating at a higher level of abstraction than the simple physical arrangement of the components on the circuit of the processor, which may not exhibit geometrical symmetries strictly speaking (the physical symmetries are not however excluded if they have their counterparts in logical or functional symmetries). For example, a processor with circuits, “cores” or computation units that are unequally distributed in the space can nevertheless be seen functionally as a set of computation units or clusters exhibiting symmetries that can be exploited by the invention. In other words, the symmetries according to the invention fall within a topological (or architectural) approach.

Advantageously, but optionally, the topology of the communication network is chosen from the list comprising: Bus, Point to Point, Daisy chain, Crossbar, Ring, Star, Tree, Fat Tree, Hypertree, Clos, Y, Delta, Omega, Hypercube, Folded Cube, Fibonacci Cube, Cube-connected cycles, and their extensions; Grid, 2D Mesh, 3D Mesh 3D Multimesh and the higher dimensions, and their extensions; 2D Torus, 3D Torus, and the higher dimensions and their extensions; hybrid of the preceding topologies; Fully connected (i.e. complete or Full Mesh).

Regarding the topology symmetries (or topological symmetries), a graphic modeling approach is possible. The physical and/or logical topology of a computation platform (e.g. multicore processor, multiprocessor, computation server, etc.) can in fact be modeled by a graph G(V,E) (oriented or not, weighted or not, tagged or not tagged, etc) in which the set of the nodes V models the computation units of the platform, and the set of the arcs and/or edges E models the interconnects between these units. Each node v of V can be characterized by its architecture, its computation power, its number of individual computation units, its memories and their size, the number of registers, etc (non-exhaustive list). Two nodes are said to be identical on the basis of a predefined list of characteristics if, and only if, they are identical on each of these characteristics. An interconnect e of E defined by its ends, example e=(v1,v2) (arc if oriented or edge if not oriented), and it is characterized by its capacity, the size of its buffer memories (buffers), its bandwidth, the width of its bus (in bits), etc (non-exhaustive list). Similarly, two links are said to be identical (on the basis of a predefined list of characteristics) if, and only if, they are identical on each of these characteristics.

The graph analysis techniques could be used to detect and/or analyze and/or determine and/or manage the symmetries. A graph isomorphism designates a bijection of nodes which preserves the adjacency and the non-adjacency of the nodes as well as the degrees of the edges. This bijection is said to preserve the structure of the graph. In the case where an isomorphism is defined from the graph to itself, it is called “graph automorphism” (which is the present case, the graph isomorphism is the graph representing the physical and/or logical topology to itself). The automorphisms define permutations with the characteristics which are those of the isomorphisms. In other words, it is a bijection of the set of vertices of the graph to itself which preserves the set of edges.

The geometrical symmetries can optionally be used to graphically represent an automorphism. However, this is generally dependent on the drawing representing the graph of the topology. Furthermore, certain graph automorphisms cannot be visualized graphically by a geometrical symmetry operation. In the present case, the graph automorphisms in general are considered: in no case are there limitations to just the geometrical symmetries. The symmetries are of topological nature.

A symmetry operation can be defined or interpreted in the sense of an automorphism of the graph G modeling the physical and/or logical topology of the architecture (i.e. the computation platform), whether the graph is oriented or not oriented, weighted or not weighted, tagged or not tagged (see glossary of graph theory). The graph obtained after a symmetry operation (automorphism) differs from the initial graph only by the labels of the nodes and of the edges. Their structures are completely equivalent. A simple relabeling makes it possible to restore the initial graph.

The symmetry operations transform or associate a fault scenario into or with another fault scenario that is equivalent (in form and in functionality). In other words, classes can be determined as equivalent following the application of a sequence of symmetry operations followed by a relabeling (for example). The set of scenarios is explored so as to obtain fault equivalence classes. The equivalent scenarios form an equivalence class and each equivalence class is associated with a resource allocation solution.

The symmetries (and/or symmetry operations) can be “received” (for example from an external software module or from a person designing circuits) or “determined” by analysis and computation means. Detecting the symmetries of a topology amounts to compiling the set of automorphisms of the graph G modeling the topology (“Graph automorphism problem”). In addition to the detection of the symmetries by the user or the developer, a certain number of techniques can make it possible to perform the analysis of the physical and/or logical topology, and do so automatically. These techniques include the use (possibly combinatorial) of search trees for the permutations which meet the requirements of graph isomorphism. Effective tools exist for solving this problem (Nauty, Saucy and Bliss). It is recalled that the composition of automorphisms is an automorphism. Similarly, the composition of symmetry operations is a symmetry operation. Furthermore, any symmetry operation can have associated with it a reverse operation which is then also a symmetry operation.

A symmetry operation designates a transformation which comprises (non-exhaustive list, the elements indicated being able to be combined together): displacements (preserving the oriented distances and angles), isometries (preserving the distances and the angles), similarities (preserving the distance ratios), affine transformations (preserving the parallelisms), homographic transformations (preserving the straight lines), and inversions for example (preserving all the straight lines and the circles in the plane case). A transformation can also comprise one or more bidifferentiable transformations (or diffeomorphisms), conformal or anticonformal transformations (preserving the angles), equivalent or equireal transformations (preserving the areas in the plane case), bicontinuous transformations or homeomorphisms (preserving the neighborhoods of the points), displacements (reflections, central symmetries, translations, rotations), homotheties, affinities, etc.

In a development, each of the equivalence classes (grouping together equivalent scenarios) is associated with a computation resource allocation solution. In a development, one or more equivalence classes is/are associated with one or more computation resource allocation solutions. In other words, the representations (one class, one solution), (one class, several solutions), (several classes, one solution) and (several classes, several solutions) are possible.

In a development, the determination of the equivalent scenarios is performed by application of an inference engine. The inference engine can be based on symmetry operations or even use tools making it possible to resolve graph isomorphisms (determine that two finite graphs are isomorphic, i.e. bijection between the vertices which preserves the edges). Various symmetry detection software tools can be used.

In a development, the determination of the equivalent scenarios comprises the association of a set of identifiers with each fault scenario. Each scenario has associated with it a set of identifiers, each of these identifiers corresponding to an order of formulation of the faults of the scenario. It may be that two different formulations result in a same identifier. In this case, it is entered just once. The identifiers have several properties. Two equivalent scenarios have the same set of identifiers. If one identifier is common to the sets of identifiers of two different scenarios, then these scenarios are equivalent. Then, to prove the equivalence of two scenarios, it is sufficient to find an identifier that is common to both.

To do this, one way to proceed consists in a) choosing a scenario from all the scenarios not yet tested, testing the equivalence by computing one of its identifiers and by checking its association with the sets of identifiers of the equivalence classes already identified. If in the step b), the comparison shows that the identifier of the scenario tested belongs to one of these sets, then the scenario is indicated as being tested, the next step c) is skipped to go directly to the step d). Otherwise, in the step c) a new class is created, an equivalence class whose tested scenario becomes the “representative”. The set of its identifiers is then computed and these identifiers are saved for subsequent tests. In the step d), if the set of fault scenarios not yet tested is not empty, the step a) is repeated (recursive method). Otherwise, the algorithm is terminated because all the scenarios will have been covered (and all the equivalence classes and their identifiers will have been determined).

In a development, the determination of the equivalent scenarios comprises the association of a unique identifier with each fault scenario. In order to avoid saving the sets of identifiers and to accelerate the identification of the equivalent scenarios, it is possible to use identifiers which exhibit the characteristic of having a total order relationship. The identifiers can then be ordered and it then becomes possible to compute the minimum (respectively the maximum) of a set of identifiers according to this order relationship. This minimum (respectively maximum) is the same for equivalent scenarios. The technique previously described is used again, but this time by using (computing, comparing and saving) only the minimum (respectively maximum) of the identifiers of a scenario and of its equivalence class. This minimum (respectively maximum) will advantageously be computed by employing an alphabetical/alphanumeric labeling and character concatenation techniques, this development will be detailed below.

In a development, the unique identifier is obtained by concatenation of the character strings forming said identifiers. The character strings can be numeric (e.g. 5125255) or alphabetic (e.g. abhdgjkie) and/or alphanumeric (54sde454h). The integers (all bases included: binary, decimal, octal, hexadecimal, etc.) and the character strings exhibit this aspect of existence of a total order relationship, but an order relationship can be defined exhaustively on any set. For example, it is possible to establish a total order relationship Ron the set {0,1,a,b,bx} according to which bx>0>a>1>b. All that is required is that a relationship be total, in other words capable of ordering all the possible words that can possibly be composed from a given alphabet (in the mathematical and not just alphanumeric sense). The concatenation technique proposed is effective and rapid.

In a development, the symmetries comprise one or more axial rotations about an axis comprising one or more computation units, according to angles −90°/+90/+180° and one or more vertical or horizontal displacements or shifts.

In a development, the equivalent fault scenarios are determined by combinatorial exploration, said combinatorial exploration comprising the construction of one or more equivalence class trees.

In a development, the method further comprises the creation of a file specifying the allocation of resources.

In a development, the method further comprises the determination of a compression rate for the fault scenario space, the compression rate being associated with the type of architecture of the processor.

In a development, the method for decompressing all the fault scenarios of a processor, after the startup of the processor, comprises the determination of one or more faults associated with one or more computation units on starting up the processor; the characterization of the corresponding fault scenario; the identification of the fault equivalence class and of the computation resource allocation solution associated with said fault equivalence class.

In a development, the method further comprises the reconfiguration of the processor started up, the reconfiguration comprising the application to the processor of the computation resource allocation solution.

A “reconfiguration” designates an operation which consists in replacing tasks on new computation resources other than those which were initially assigned to them. This also means recomputing new routing paths which result from the replacement of these tasks.

In a development, the reconfiguration is performed at the moment of, or after, the occurrence of one or more faults of one or more computation units of the processor in order to continue the execution of the application on the processor.

In a development, the reconfiguration is performed before the occurrence of one or more faults of one or more computation units of the processor preventively, one or more faults being simulated or anticipated. In particular, one or more reconfigurations can be performed preventively, in order for example to preserve the life span of a processor. This technique can be combined with the “dynamic temperature management” (DHM) of the computation units of the processor.

In a development, the method comprises the classification of the processor in a range grouping together processors with an identical number of failing computation units. A range groups together all the architectures with a topology that meets certain predefined criteria. These criteria are generally global (global computation capacity, global bandwidth, etc.) to which can be added more specific criteria (e.g. architecture comprising x computation units of capacity C, x′ computation units of capacity C′ and y links of bit rate D, y′ links of bit rate D′, etc). The graph automorphisms define graph equivalence relationships. In the present case, the graph automorphisms (i.e. symmetry) make it possible to define topology equivalence classes which partition all the topologies of a range. Each partition assembles graphs of topologies which are equivalent according to the predefined characteristics to within an automorphism.

In a development, a failing computation unit is associated with a failure rate or confidence of execution rate, said failure being total or partial. According to a specific embodiment, computation units in a binary state are manipulated: these computation units are functional or they are not. The management of the faults as described guarantees a better certainty of execution on healthy cores. Nevertheless, according to other embodiments, as complement to the preceding implementation or as replacement thereof, a probabilistic or “layered” approach can also be pursued. For example, a computation unit can be associated with a “confidence of execution rate”. A healthy unit will then have for example a confidence rate of 100%, but a computation unit with a memory that is partially out of commission (or exhibiting other problems) will be able to be associated with a confidence rate of 80% (for example). With this type of mechanism, it is possible to obtain a segmentation that is richer and finer in terms of allocation of the computation resources (and of “ranges” of processors, that is to say with properties more precisely differentiated). It is stressed that this type of solution can perfectly well be combined with (e.g. complement) the so-called “spare” approaches or other mechanisms that aim to ensure a robustness to faults of the processors.

In a development, the method further comprises the identification of one or more symmetrical links from the determination or the reception of one or more topology symmetries. The symmetrical links designate the interconnects, i.e. the communication links between the computation units. Once the symmetries of the topology of the network have been received or computed, a set of symmetrical links can be determined. Subsequently, after labeling, these symmetrical links can be manipulated, for example to determine the equivalence classes.

A computer program product is disclosed, said computer program comprising code instructions making it possible to perform any one of the steps of the method when said program is run on a computer.

A system is disclosed for compressing or decompressing the fault scenario space of a processor, the system comprising means for implementing any one of the steps of the method.

### DESCRIPTION OF THE FIGURES

Different aspects and advantages of the invention will become apparent from the description of a preferred, but nonlimiting, mode of implementation of the invention, with reference to the figures below:

FIG. 1 schematically illustrates a manycore processor with 9 clusters;

FIG. 2 illustrates an example of relabeling after a symmetry operation;

FIG. 3 illustrates the correlation between a fault scenario mapping/routing solution and an equivalent fault scenario;

FIG. 4 illustrates two examples of scenarios with three faults;

FIGS. 5A and 5B illustrate the concept of symmetrical distance;

FIG. 6 illustrates the equivalence of two examples of scenarios and the computation of identifiers;

FIGS. 7A, 7B and 7C illustrate different aspects of the method.

### DETAILED DESCRIPTION OF THE INVENTION

A “multicore” microprocessor is a processor that has a number of physical cores which work in parallel. A physical core is a set of circuits capable of executing programs autonomously. All the functionalities necessary to the execution of a program are present in these cores: ordinal counter, registers, computation units, etc. The term “multicore” is generally employed to describe a processor composed of at least two cores (or computation units) etched within the same chip. These computation units can be clustered (or not). The computation units are interconnected by a communication network (Network on Chip or NoC).

The recent technological advances in the design and creation of circuits now make it possible to produce processors containing a large number of generic cores (from a few tens to several hundreds) with complex memory hierarchies: these are no longer called “multicore” but “manycore” systems.

A certain number of problems are due to the increase in the number of cores. For example, this increase brings about a situation in which the interconnections become the bottleneck in the quest for performance. To the different execution constraints are thus added particular parallel programming techniques to exploit all the potential of the circuit (run time layer development, performance analysis, distributed control, compilation, management of communications on a network on chip, etc).

The use—and therefore the marketing—of a degraded chip can be obtained by different means and/or methods.

A first approach consists in performing an allocation (mapping and routing) of an application (software) to the computation and communication resources of a degraded manycore processor. Generally, these operations are done statically and “offline” (that is to say, when the chip is not powered up). These techniques will also assume a total and entire knowledge of the architecture of the processors on which the software application will be deployed. For example, one approach to make it possible to sell these degraded processors may consist in defining computation power ranges. A given range then gathers together all the processors which guarantee the availability of a set overall minimum of computation resources. Thus, by following this marketing strategy and because of the absence of differentiation according to the location of the healthy resources, processors corresponding to different architectures may be found within a same range. For example, in the example of a manycore with an architecture providing 16 computation clusters for which the range of degraded processors derived from this manycore comprises only 15 functional clusters (a single cluster being faulty), there are then 16 possible architectures in this range. Each architecture corresponds to the case of one of the 16 clusters in failure state. There then arises the problem of the deployment of a same application on manycore processors with the same global computation capacity but with an architecture that differs from one processor to another. In effect, the information is known only very late, when the processor is switched on. Consequently, this mapping/routing technique is limited.

It is possible to provide a solution that makes it possible to “reconfigure” the deployment of the application on the chip according to the fault scenario thereof. In the absence of such a solution, the degraded processors cannot be fully exploited and cannot be marketed as is. Most of the current multi/manycore processors use shared buses (for example the ClearSpeed CSX manycore) or certain types of NoCs of RING type. These circuits tend to eliminate the problem of reconfiguration by eliminating the combinatorial explosion of possible fault scenarios thereof. In fact, the patent literature does not as yet even mention this technical problem (and a fortiori does not propose any technical solution). However, these circuits with shares buses or NoCs of RING type are not scalable and the next generations of manycore processors will probably have to dispense with this type of circuit to adopt NoCs of “2D Torus”, “3D Torus” or other such types for which this technical problem will be acute.

Another possible approach consists in modifying the hardware, for example with the implementation of special routers. This solution may complement the examples disclosed herein.

Regarding the exploration of the space of the architectures for solving the problem of deployment, a first solution consists in exploring all the space of the architectures of a range and reiterating the mapping/routing algorithms for each architecture (fault scenario) and saving the solutions obtained. When a chip is started up, it is then possible to detect what its architecture is and use the corresponding solution. By construction, this technique is exact (i.e. optimal) and provides the guarantee, in the compilation phase, of the possibility (or not) of deploying the application whatever the fault scenario within a range. However, this technique is generally costly in execution time because the number of configurations to be explored is very great. A problem of storage of the solutions also arises because of the huge size of the binary which results therefrom. In effect, with each fault scenario requiring its own binary, the size of the final binary could be very great if all the reconfigurations for the specified range had to be stored.

By contrast to the techniques previously mentioned, certain embodiments of the invention make it possible to advantageously process the faults in terms of computation resources. Certain embodiments of the invention in effect consider processors with an NoC that is entirely functional, that is to say without router (or link) fault. The communication links and the routers are generally less subject to faults.

It is stressed that the techniques disclosed hereinbelow apply to the mapping and to the routing (both). In order to avoid additional notations which would complicate the description, only the mapping will be mentioned hereinbelow, but the disclosure will apply equally to the routing (routing links).

The term “resource allocation” consists of mapping and routing operations that make it possible to allocate the computation and communication resources necessary to execute the different tasks of an application and have them communicate.

The term “mapping” therefore designates the operation which assigns each of the tasks of an application to execution media (i.e. computation units, e.g. core, processor, cluster, server, etc.), which implicitly presuppose memory means. The tasks assigned to one or more media will then be executed solely thereby. The scheduling at a medium level will determine the order and the times for which the tasks access these shared resources (which are allocated to them).

The term “routing” designates the operation which computes a path made up of communication links which link the computation units (Bus, NoC, local area network, internet, etc.) in order to ensure the transfer of data between tasks which communicate with one another and which are executed on different media.

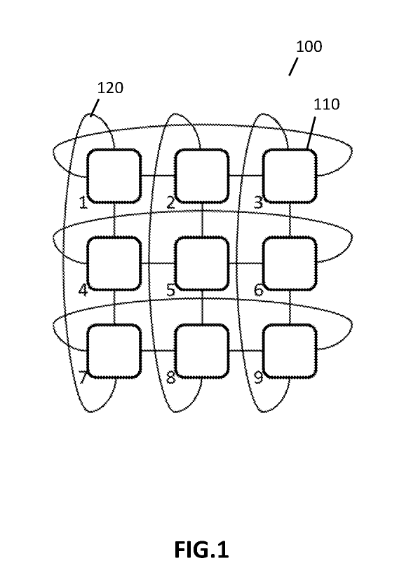

FIG. 1 schematically illustrates a manycore processor 100 with 9 clusters 110 (or “cores” or “computation units”) of 3×3 2D Torus type. The clusters are numbered from 1 to 9 and are interconnected by an NoC or interconnections 120 (represented by the lines in the figure). Most manycore processors comprise symmetries. These symmetries make it possible to define operations which transform the initial architecture into another which is totally identical to it (the architecture is said to be “equivalent”) in terms of form and of functionalities. Through the architecture of its NoC, a 2D Torus homogeneous manycore processor comprises several symmetries. Some symmetries are shared with the underlying mesh (checkerboard) architecture. In the example of FIG. 1, the following can for example be encountered: axial rotations in the plane of the mesh (relative to a straight line which passes through it at right angles at the level of the cluster 5, of)−90°/+90/+180°; a rotation of 180° in the space around an axis which passes through the clusters 2, 5 and 8; another rotation of 180° in the space around an axis which passes through the clusters 4, 5 and 6; a rotation of 180° in the space around an axis which passes through the clusters 1, 5 and 9; a rotation of 180° in the space around an axis which passes through the clusters 3, 5 and 7. The links on the edges of the 2D Torus give rise to additional symmetries: a vertical displacement or shift of the lines of clusters by one pitch upward or downward; and a horizontal displacement or shift of the columns of clusters by one pitch to the left or to the right. These last two symmetries sometimes justify the adoption of a 2D Torus architecture rather than an asymmetrical mesh architecture on the edges (mapping and routing are highly dependent thereon).

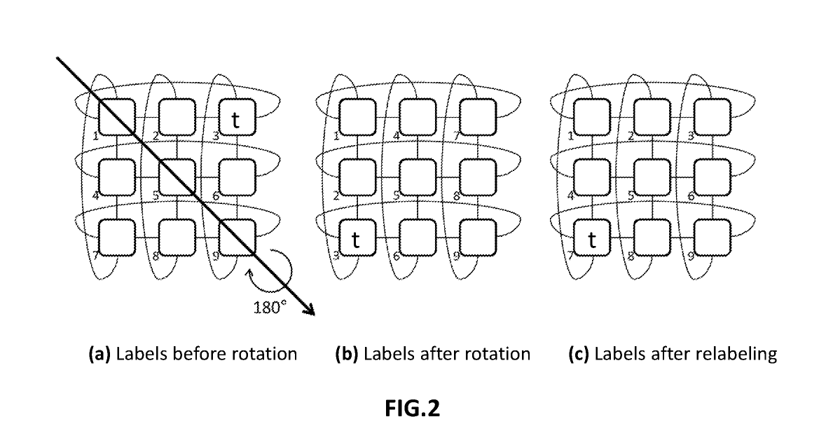

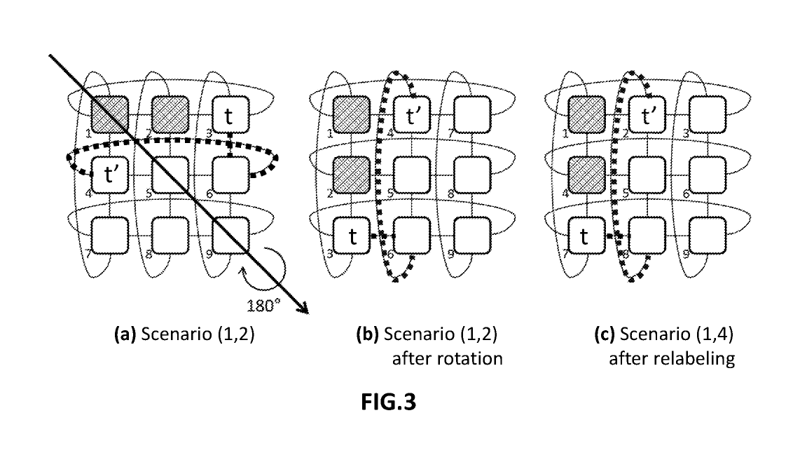

FIGS. 2A, 2B and 2C illustrate the labeling before and after a symmetry operation. FIG. 2A shows the labels before the symmetry (of rotation). FIG. 2B shows the labels after the rotation. FIG. 3B shows the labels after relabeling.

Each symmetry operation has associated with a relabeling function which makes it possible to restore the initial order of the labels of the architecture. For example, the cluster relabeling function [1,4,7,2,5,8,3,6,9]->[1,2,3,4,5,6,7,8,9] corresponds to the rotation of 180° in the space around the axis which passes through the clusters 1, 5 and 9. The same applies for the interconnects whose labels are not mentioned or represented in the interests of simplification.

A fault scenario is defined by the number and the location of the computation units (i.e. of the clusters in the present example) which are defective. For example, in a scenario with three faults, a scenario for which only the three clusters i, j and k are faulty will be denoted a scenario (i,j,k). The order of formulation of these faults is unimportant, i.e. the scenarios (i,j,k), (i,k,j), (j,i,k), (j,k,i), (k,i,j) or (k,j,i) are the same.

FIGS. 3A, 3B and 3C make it possible to show how the symmetry can be used to compress the space of the fault scenarios. FIG. 3A illustrates a simplified example of a scenario with two faults (1,2). FIG. 3B shows the scenario (1,2) after rotation. FIG. 3C shows the relabeling after the rotation.

By applying a symmetry operation (FIG. 3B) followed by a relabeling (FIG. 3C), it is illustrated that the two scenarios (1,2) and (1,4) are the two facets of a same situation (which is that of two adjacent faulty clusters). By combining even more symmetry operations like the horizontal and vertical shift, similar conclusions can be drawn for scenarios like (2,3), (1,3), (1,7), (3,6), (3,9), etc. All these scenarios are equivalent to the scenario (1,2) and form what can be called an “equivalence class” of fault scenarios. An equivalence class contains exclusively scenarios which can all be brought, by sequences of symmetry operations, to a same and unique fault scenario (which is therefore equivalent to them). The latter is thus designated as the representative of the equivalence class. Given the property of transitivity of an equivalence relationship, any scenario can be designated as representative of the class to which it belongs. In the present example, the scenario can be chosen and the equivalence class can then be designated by the class (1,2).

Defining equivalence classes presents the advantage of not having to solve the mapping/routing problem and of saving the solution only for the single and unique representative of each class. By having available the sequence of symmetry operations, to bring a scenario to the representative of its class, it is possible to use this same sequence to reverse the order of application of the symmetry operations in order to relabel the solution of mapping/routing of the representative as a solution of exactly equal quality for the scenario concerned. This scenario will be known on startup of the chip.

In the example of FIG. 3, to compute a mapping/routing solution for the scenario (1,4) represented in FIG. 3C from the solution associated with the scenario (1,2) represented in FIG. 3A, it is possible to apply the function of relabeling of the clusters and of the interconnects associated with the rotation of 180° about the axis passing through the clusters 1, 5 and 9.

In the example of the scenario (1,2) represented in FIG. 3A, two computation tasks t and t′ are placed respectively on the clusters 3 and 4 (not failing), and communicate by using the path 3->6->4 which is made up of the direct interconnects 3->6 and 6->4. If a scenario (1,4) applies, i.e. a degraded chip with the failing clusters 1 and 4, the task t′ can no longer be performed and a re-mapping should be carried out. After this re-mapping, the task t will be placed on the cluster 7, and the task t′ will be placed on the cluster 2 after a symmetry of rotation of 180° about this axis passing through the clusters 1, 5 and 9. The communication between t and t′ will be performed through the path 7->8->2. Regarding the impact of the reduction or compression of the scenario space by the exploitation of a symmetry (here a rotation), the class (1,2) contains 18 equivalent fault scenarios which corresponds to a potential compression rate of 1−1/18=94.44%. This compression rate applies equally to the computation time and to the mapping/routing solutions save file.

The method for putting this compression into practice is described hereinbelow.

After the identification of the fault scenario equivalence classes (when the symmetry operations which save the structure of an architecture are explored and itemized), these same classes are exploited in order to proceed with the partitioning of all the fault scenarios. The number of scenario space partitioning possibilities corresponds to the Bell number which is exponential in the size of the set concerned.

For the partitioning, a first solution could consist in implementing an inference engine based on rules of symmetry, implemented for example by means of languages such as LISP or Prolog. Starting from a given scenario, the inference engine sets out to search for a sequence of rules to be applied in order to establish an equivalence with the representative of a class already listed or to create a new equivalence class if no equivalence is established (i.e. absence of sequence). In the latter case, this scenario becomes the representative of the new class. To implement such an inference engine, it is then necessary to define a) the rules of symmetry and the relabeling operations which are associated with them and b) the priority (or the order or the occurrence) of application of each of these rules and do so on each step of the search process (the priorities, orders or occurrences being able to vary from one step to another of the search process). The symmetry operations are not provided with good characteristics with respect to the composition. For example, they are not generally commutative, i.e. for two operations O1 and O2, O1*O2 gives a different result from O2*O1. Similarly, they are not idempotent: O1*O1=/=O1. These characteristics generally make the definition of an order/occurrence of application of the symmetry operations very complex. It is then difficult to define a search strategy which optimizes the execution time. Furthermore, there is a risk of having therein a number of exceptions to the predefined order which have to be taken into account according to the architecture. Moreover, when the symmetry is used, it is tempting to rely on intuition to establish these parameters but this will soon prove, in many cases, to be very complex and counterproductive for the identification of the equivalence classes. The characteristics of the symmetry operations also pose a problem of definition of the stop conditions for an inference engine. Since the number of compositions of operations possible is very great, when no equivalence with a case already listed is found, it is not generally possible to say at which moment it is possible to stop the inference engine and to conclude on the presence of a new equivalence class. If the stop condition is too restrictive, the technique also risks not being exact and the maximum compression rate might not be reached (a class could correspond to several partitions, if the equivalence between all its elements is not established). The adaptation of such a method for each architecture will also take a long time and be very complex.

These reasons make the development of an effective and generic inference engine irrelevant, in the general case.

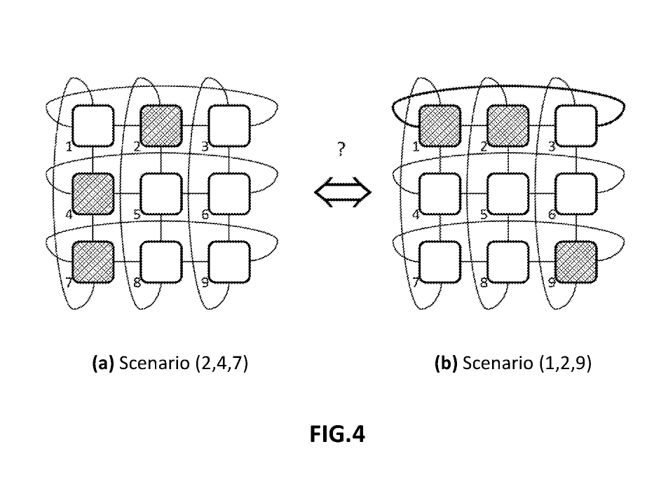

FIG. 4 serves as a support for illuminating the complexity of the technical problem consisting in identifying equivalent cases. FIG. 4 shows two scenarios with three faults. FIG. 4A shows a scenario (1,2,9) and a scenario (2,4,7). To show that these scenarios are equivalent, a rotation in the plane of +90° in the clockwise direction around the central cluster 5 changes the labels of the adjacent clusters 4 and 7 to 1 and 2. The cluster 2 becomes 6. To transform the fault of the cluster 6 into a fault of the cluster 9, the application of a horizontal shift downward to the scenario (1,2,6) leads to the scenario (4,5,9). Then, by applying to this latter scenario an axial rotation of 180° about the axis which passes through the units 4, 5 and 6, and after labeling, the scenario becomes (4,5,3). The application of a reverse horizontal shift, upward, and the scenario obtained becomes (1,2,9). By the application of this series or sequence of transformations, exploiting the symmetries of the circuit, it is therefore possible to establish the association of the scenarios (1,2,9) and (2,4,7) with the same equivalence class (that can be represented or denoted (1,2,6), by following, for example, a criterion of minimization of the sums of the labels).

The ex ante knowledge of the equivalence makes it possible to persevere in the combination and the search for the sequence of symmetry operations. Without this prior knowledge, the stop problem could become critical. The demonstration which has just been made for the example might not stop, or by default (i.e. if a stop was triggered) might culminate in the incorrect conclusion of the non-equivalence of the scenarios (and therefore in the conclusion of the existence of two equivalence classes). This first search approach remains possible, but it is limited.

Another embodiment of the compression of the space of the scenarios is described below. This method is rapid and generic. According to this embodiment, each scenario is associated with an identifier, so that two scenarios associated with a same identifier are necessarily or inevitably equivalent and are therefore interchangeable. According to one embodiment, the identifier can be that of the equivalence class itself. By construction, such an identifier incorporates the transformations of symmetry and does not depend on the labels associated with the failing clusters. To this end, a distance is introduced: an inter-cluster distance which adds the concept of symmetry to the usual inter-cluster distances. Then, by using this new distance as a basis, means and/or steps make it possible to identify a particular scenario.

In detail, the compression method comprises four steps or phases.

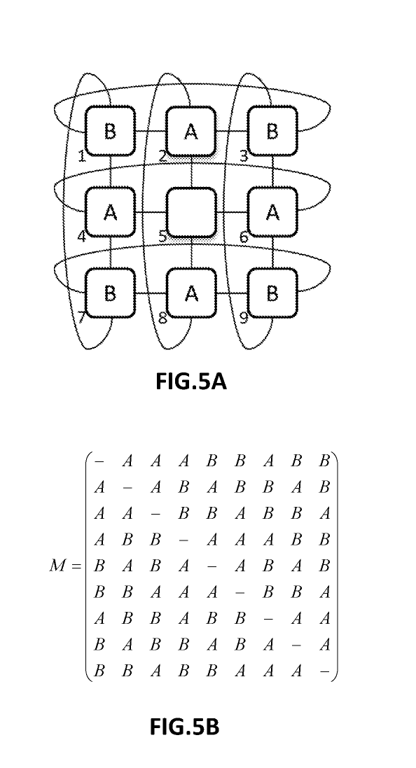

In a first step, a distance is defined that is called “symmetrical inter-cluster distance”. To define the fault scenario identifier, a means of identification of the clusters at equivalent distance from another cluster is described hereinbelow. To define an inter-cluster distance, a first solution consists in taking into account the number of links which separate these clusters (e.g. hop count). This measure makes it possible to assess the shortest inter-cluster routing path length and thus gives a measurement for the data bit rate consumed relative to the overall routing capacity of the network. The smaller this is, the more the congestion of the network can be avoided (and energy saved). The improved inter-cluster distance proposed here takes into account—in addition to the hop count and the nature of the interconnects—the patterns of symmetry. By corollary, two pairs of clusters which are at different hop counts will have different “symmetrical distances”. These distances are introduced in FIG. 5.

FIGS. 5A and 5B illustrate the concept of symmetrical distance. Take a computation unit denoted Ui. Unit Uj and Uk are said to be at the same “symmetrical distance” from Ui if there is a sequence of symmetry operations that makes it possible to save the location of Ui while bringing the location of Uk back to that of Uj. FIG. 5A gives an example for the 3×3 2D Torus and the cluster 5. By rotations of −90°/+90°/+180° in the plane around the cluster 5, it emerges that the clusters 2, 4, 6 and 8 are at the same symmetrical distance from the cluster 5 labeled as distance A. Similarly, the clusters 1, 3, 7 and 9 are at the same symmetrical distance from the cluster 5 and are labeled B. The result of all the clusters can be grouped together in a symmetrical distance matrix M represented in FIG. 5B, of 3×3 dimension. Mij is the distance between Ui and Uj. By construction, there are as many equivalence classes with two faults as there are types of symmetrical links (i.e. of symmetrical distances). For example, for the matrix M of the 3×3 2D Torus, the number of symmetrical links is two (A and B). In this case, there are two equivalence classes for the scenarios with two faults. Since the number of possible architectures with two faults is 36 (the number of combinations of 2 out of 9), the compression rate is 1−2/36=94.44%.

According to the symmetries detected and exploited in order to define the symmetrical distances (for example by a developer implementing reconfiguration software for a given chip), different matrices can be obtained. The greater the number of symmetries exploited, the better the compression. For example, if a developer considers that the clusters 6 and 2 are not at the same symmetrical distance from 5 because he or she disregards the axial rotation about the center, then he or she will have to label one of these distances some other way, C for example. This will automatically increase to 3 the number of equivalence classes for the range with 2 faults and will thus reduce the compression rate to 91.66%. This rate will be reduced all the more if it is considered that this same developer would surely have neglected other symmetries on the distances denoted B initially in the matrix of the example and will then have to define additional distances D, E and F. In this case, the compression rate drops to 83.33%.

To designate the symmetrical distances, it is possible to use numerical labels in place of the alphabetical labels, but the latter greatly simplify the computation and the comparison of the identifiers of scenarios thereby allowing for the implementation of more generic and more effective algorithms.

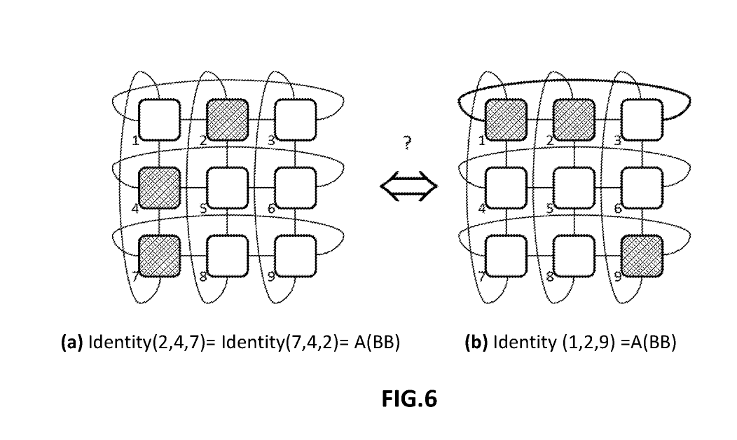

FIG. 6 introduces the scenario identifiers and illustrates a use thereof to establish the equivalence of the fault scenarios (2,4,7) and (1,2,9) provided previously in FIG. 4.

In a second step of the compression method, a fault scenario is identified and characterized. To do this, the positions of the faults relative to one another are used, by means of the concept of symmetrical distance defined previously.

In one embodiment, the identifier of a scenario (and therefore of its equivalence class) is a word taken from an alphabet made up exclusively of the labels of the symmetrical distances. For a scenario with two faults (Ui,Uj), the identifier denoted Identity(Ui,Uj) is given by the distance Mij. It should be noted that the brackets in the identifier are necessary neither for the definition nor for the comparison of the identifiers. These brackets are represented only to make it easier to read and show the transition from one fault to the next, but they can be deleted on implementation.

For a scenario with three faults (Ui,Uj,Uk), the identifier Identity(Ui,Uj,Uk) is obtained by Mji(MkiMkj). For the scenarios with a greater number of faults, recurrence is applied by using a character string concatenation operator. By using Identity(Ui, Uj, . . . , Um) to designate the identifier of the scenario (Ui, Uj, . . . , Um), then Identity(Ui, Uj, Uk, . . . , Um, Uq) corresponds to the concatenation of Identity(Ui, Uj, . . . , Um) and (MqiMqjMqk . . . Mqm). Since the concatenation is not symmetrical, the identification depends on the order considered in the formulation of the faults of the scenario. In other words, with no additional method, several identifiers can be computed for a same scenario. In order to avoid equivalent scenarios being detected as such because of the order of the formulation of the faults, an additional and optional step makes it possible to make sure that they have a unique identifier and therefore ensures the accuracy of the technique and a maximum compression rate. In one embodiment, the order of formulation of faults which gives the smallest identification with respect to the comparison of the character strings is selected. The benefit of the concatenation for the comparison of the identifiers justifies the use of alphabetical labels. Alternatively, alphabetical, numeric and/or alphanumeric characters can be used. By applying this identification technique to the example of FIG. 6, it is possible to show that the scenarios (2,4,7) and (1,2,9) are equivalent. In effect, M47(M27M24)=A(BB) and M21(M91M92)=A(BB).

In conclusion, the use of identifiers encoding the symmetries makes it possible to dispense with the description of a sequence of symmetry operations in order to demonstrate the equivalence of the scenarios.

When the number of faults is greater than half the number of units initially provided on a chip, rather than defining a scenario through its units with faults, it may be prudent to define it through its functional units to optimize the size of the scenario identifiers. The technique for computing the identifier Identity will remain valid by relating the positions of the healthy units relative to themselves. For example, from 5 faults, it is more efficient to list the remaining 4 healthy clusters of the 3×3 2D Torus.

In a third step of the compression method, the space of the scenarios is explored. During this step, an equivalence class tree is constructed. This operation consists in scanning the space of the possible fault scenarios in order to partition it into equivalence classes according to the definition given during the preceding step. For each scenario scanned, a check to see if the tree does not contain a listed scenario which is equivalent to it is carried out. If that is not the case, a new node is added to the tree (the scenario and its identifier being the representatives of the new equivalence class). The different levels of the tree indicate the different ranges. For example, at the top of the tree, there are the classes of the range with a single fault. In the example of the 3×3 2D Torus type processor, it is made up of only a single node. The construction of the tree stops when the maximum fault level considered (i.e. the most degraded range) has been reached. This tree is constructed just once for each manycore architecture because it is independent of the applications which will be deployed therein. The supplier of the manycore processor will be able to construct and incorporate this tree in the development tools (for example). The users or developers will also be able to use such trees, for example when designing applications in order to compute and save the mapping and/or routing solutions for each of the nodes of the level which represents the range on which they want to deploy the application.

In the case of the exploration, given that it is not possible to know previously whether two given scenarios are equivalent or not, the use of an identifier is found to be particularly advantageous: it makes it possible to state that two scenarios are equivalent even though the sequence of symmetry operations necessary to transform one scenario into another remains unknown (not available, not documented, not accessible, etc).

Optionally, different variants of the explorer can be implemented, for example with the choice of a widthwise or depthwise search, according to different choices of the representative of an equivalence class (for example choosing the one for which the labels of the clusters are the smallest).

For most manycore processor architectures, the space explored in order to construct the tree of the equivalence classes can itself be reduced. In effect, it is not always necessary to scan the entire space. For the example of the 3×3 2D Torus, any fault can be brought back—by symmetry operations—to be placed (or relabeled) as fault of the cluster 1. In order to reduce the space to be explored, it is therefore possible to consider that the computation unit number 1 is always faulty. Thus, the size of the space to be explored is divided by 9. Optionally, for greater certainty, a test can also be implemented in order to check that the tree of the equivalence classes obtained does indeed cover all the possible scenario cases.

In a fourth step of the compression method, a relabeling is performed. After the startup of the chip and the detection of the fault scenario, the identifier and therefore the equivalence class to which the chip belongs can be determined according to the technique presented in the second step. Thus, it is possible to extract, from the tree of the scenarios constructed during the phase 3, the equivalent scenario and the mapping/routing solution which are associated with the fault situation of the chip. It will then be necessary to adapt this equivalent solution to the scenario of the chip. This adaptation constitutes the relabeling step or phase.

This relabeling step is executed on the chip since there is a need to know the fault scenario. In an embedded execution context, this phase can be optimized because of or for resources that are limited in computation and memory terms (low complexity in execution time and space).

In some cases, the NoC architecture can be the same for all the manycore processors (when, by assumption, the NoC is entirely functional or fault-free). The relabeling step proposed consumes little in computation terms. In effect, contrary to the reasons which urge relativizing the use of an inference engine, the fact of knowing previously that two scenarios are equivalent (by computing their identifier and therefore the order of formulation of the faults) makes possible the determination of a sequence of symmetry operations which is both generic and effective for bringing a scenario back to another which is equivalent to it. For example, for a 4×4 2D Torus, the algorithm requires fewer than 3 instructions to detect the sequence and thus relabel a scenario to its equivalent. For that, from the moment when the first fault is known according to the order which has been obtained for the computation of the identifier, it is sufficient to bring this fault back to the fault 1 by performing the necessary vertical and horizontal shifts. Then, the axial rotation (if necessary) will determine the rest of the faults. This algorithm is of O(1) complexity, that is to say the lowest there is.

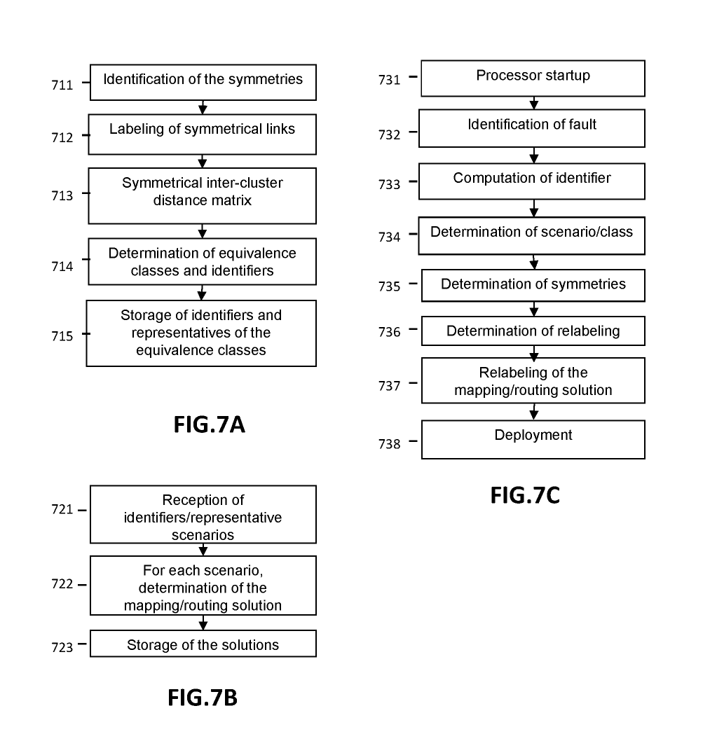

FIGS. 7A, 7B and 7C illustrate different aspects of the method. FIG. 7A illustrates examples of operations generally performed offline (processor off). Generally, these operations do not depend on the software applications “mapped” onto said processor. The symmetries are identified in the step 711. The symmetrical links are labeled in the step 712. The symmetrical inter-cluster distance matrix is constructed in the step 713. The exploration of the scenarios (equivalence classes and identifiers) is performed in the step 714. The storage of the identifiers and of the representatives of the equivalence classes is performed in the step 715.

FIG. 7B illustrates examples of operations generally performed offline (processor off), for the deployment of a software application for example. In the step 721, the scenarios representative of classes and their identifiers are received or identified or computed. In the step 722, for each class representative scenario, the appropriate mapping/routing solution is computed. In the step 723, the solutions are stored (each solution can specify the scenario for which it has been computed).

FIG. 7C illustrates examples of operations generally performed at the time of, or after, the startup of the chip (for example after the deployment of an application according to FIG. 7B). The steps itemized below can be performed (some steps may be optional or modifiable or modified or the required data received from external modules, etc). Step 731: startup of the chip. Step 732: identification of the fault scenario. Step 733: computation of the identifier of the fault. Step 734: recovery of the scenario representing the class bearing the same identifier as that of the fault scenario observed on the processor. Step 735: computation of one or more sequences of symmetry operations making it possible to bring the fault scenario of the processor back to that of the representative of its equivalence class. Step 736: computation of the relabeling from the sequence of symmetry operations having been obtained. Step 737: relabeling of the mapping/routing solution associated with the representative of the class. Step 738: deployment of the application according to the relabeled mapping/routing solution.

The invention will be advantageously applicable for “Cloud Computing”, distributed computation environments, “Grid Computing”, etc. In addition to the virtualization of applications (eliminating the specifics of code execution on a stock of heterogeneous processors), the invention can in fact make it possible to manage faults over a set of processors, because of the topological abstraction which is performed to exploit the symmetries. In a simplified example, a processor with 800 cores can be topologically equivalent to two hundred processors with 4 cores. Consequently, the exploitation of the symmetries in both cases carry the same advantages, namely static reconfigurations (packaging in ranges, pre-marketing) even dynamic reconfigurations during runtime.

The present invention can be implemented from hardware and/or software elements. It can be available as computer program product on a computer-readable medium. The medium can be electronic, magnetic, optical, electromagnetic or be a broadcast medium of infrared type.

1. A method implemented by computer for compressing all the fault scenarios of a processor comprising computation units interconnected by a communication network having topology symmetries, each fault scenario corresponding to the number and the location of one or more failing computation units and the method comprising the steps of:
reception or determination of one or more topology symmetries;
determination of the equivalent scenarios by means of said topology symmetries;
each of the fault equivalence classes being associated with a resource allocation solution determining a specific mapping of the tasks of the applications on the computation units and a specific routing of the data exchanges over the communication network.

2. The method as claimed in claim 1, the determination of the equivalent scenarios being performed by application of an inference engine.

3. The method as claimed in claim 1, the determination of the equivalent scenarios comprising the association of a set of identifiers with each fault scenario.

4. The method as claimed in claim 3, the determination of the equivalent scenarios comprising the association of a unique identifier with each fault scenario.

5. The method as claimed in claim 4, the unique identifier being obtained by concatenation of the character strings forming said identifiers.

6. The method as claimed in claim 1, the symmetries comprising one or more axial rotations about an axis comprising one or more computation units, according to angles −90°/+90/+180°, and one or more vertical or horizontal displacements or shifts.

7. The method as claimed in claim 1, the equivalent fault scenarios being determined by combinatorial exploration, said combinatorial exploration comprising the construction of one or more equivalence class trees.

8. The method as claimed in claim 1, further comprising the creation of a file specifying the allocation of resources.

9. The method as claimed in claim 1, further comprising the determination of a compression rate of the fault scenario space, the compression rate being associated with the type of architecture of the processor.

10. The method as claimed in claim 1 for decompressing all the fault scenarios of a processor, after the startup of the processor, further comprising:
the determination of one or more faults associated with one or more computation units on starting up the processor;
the characterization of the corresponding fault scenario;
the identification of the fault equivalence class and of the computation resource allocation solution associated with said fault equivalence class.

11. The method as claimed in claim 10, further comprising the reconfiguration of the processor started up, the reconfiguration comprising the application to the processor of the computation resource allocation solution.

12. The method as claimed in claim 11, the reconfiguration being performed at the moment of, or after, the occurrence of one or more faults of one or more computation units of the processor in order to continue the execution of the application on the processor.

13. The method as claimed in claim 11, the reconfiguration being performed before the occurrence of one or more faults of one or more computation units of the processor preventively, one or more faults being simulated or anticipated.

14. The method as claimed in claim 1, further comprising the classification of the processor in a range grouping together processors with an identical number of failing computation units.

15. The method as claimed in claim 1, a failing computation unit being associated with a failure rate or confidence of execution rate, said failure being total or partial.

16. The method as claimed in claim 1, further comprising the identification of one or more symmetrical links from the determination or the reception of one or more topology symmetries.

17. A computer program product, said computer program comprising code instructions making it possible to perform the steps of the method as claimed in claim 1, when said program is run on a computer.

18. A system for compressing or decompressing the fault scenario space of a processor, the system comprising means for implementing the steps of the method as claimed in claim 1.
